(19) United States
(12) Patent Application Publication
(10) Pub. No.: US 2018/0090720 A1
(43) Pub. Date: Mar. 29, 2018

(54) Flexible OLED Display Module

(71) Applicant: Universal Display Corporation, Ewing, NJ (US)

(72) Inventors: Michael Hack, Carmel, CA (US); Ruiqing Ma, Morristown, NJ (US)

(21) Appl. No.: 15/678,039

(22) Filed: Aug. 15, 2017

Related U.S. Application Data
(60) Provisional application No. 62/400,339, filed on Sep. 27, 2016.

(51) Int. Cl. H01L 51/52; H01L 51/00; H01L 27/32; H01L 51/56

(52) U.S. Cl. CPC H01L 51/5293; H01L 51/0097; H01L 2251/5338; H01L 51/56; H01L 27/322

(57) ABSTRACT

A flexible OLED display module that is capable of repetitive flexing and having a low radius of curvature is provided. According to an embodiment, a flexible OLED display module may include a first stack having a substrate, a backplane disposed on the substrate, and an organic electroluminescent layer formed on the backplane. The flexible OLED display module may further include a second stack having a lid layer, and a polarizer deposited on the lid layer. The first stacked laminated with the second stack.

This patent application claims priority to U.S. Provisional Patent Application No. 62/400,339 filed on Sep. 27, 2016, which is incorporated by reference herein in its entirety.

### FIELD OF THE INVENTION

The present invention relates to a flexible organic light emitting diode (OLED) display module.

### BACKGROUND

Opto-electronic devices that make use of organic materials are becoming increasingly desirable for a number of reasons. Many of the materials used to make such devices are relatively inexpensive, so organic opto-electronic devices have the potential for cost advantages over inorganic devices. In addition, the inherent properties of organic materials, such as their flexibility, may make them well suited for particular applications such as fabrication on a flexible substrate. Examples of organic opto-electronic devices include organic light emitting diodes/devices (OLEDs), organic phototransistors, organic photovoltaic cells, and organic photodetectors. For OLEDs, the organic materials may have performance advantages over conventional materials. For example, the wavelength at which an organic emissive layer emits light may generally be readily tuned with appropriate dopants.

OLEDs make use of thin organic films that emit light when voltage is applied across the device. OLEDs are becoming an increasingly interesting technology for use in applications such as flat panel displays, illumination, and backlighting. Several OLED materials and configurations are described in U.S. Pat. Nos. 5,844,363, 6,303,238, and 5,707,745, which are incorporated by reference herein in their entirety.

One application for phosphorescent emissive molecules is a full color display. Industry standards for such a display call for pixels adapted to emit particular colors, referred to as “saturated” colors. In particular, these standards call for saturated red, green, and blue pixels. Alternatively the OLED can be designed to emit white light. In conventional liquid crystal displays emission from a white backlight is filtered using absorption filters to produce red, green and blue emission. The same technique can also be used with OLEDs. The white OLED can be either a single EML device or a stack structure. Color may be measured using CIE coordinates, which are well known to the art.

One example of a green emissive molecule is tris(2-phenylpyridine) iridium, denoted Ir(ppy)₃, which has the following structure:

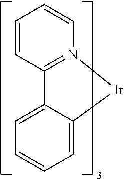

In this, and later figures herein, we depict the dative bond from nitrogen to metal (here, Ir) as a straight line.

As used herein, the term “organic” includes polymeric materials as well as small molecule organic materials that may be used to fabricate organic opto-electronic devices. “Small molecule” refers to any organic material that is not a polymer, and “small molecules” may actually be quite large. Small molecules may include repeat units in some circumstances. For example, using a long chain alkyl group as a substituent does not remove a molecule from the “small molecule” class. Small molecules may also be incorporated into polymers, for example as a pendent group on a polymer backbone or as a part of the backbone. Small molecules may also serve as the core moiety of a dendrimer, which consists of a series of chemical shells built on the core moiety. The core moiety of a dendrimer may be a fluorescent or phosphorescent small molecule emitter. A dendrimer may be a “small molecule,” and it is believed that all dendrimers currently used in the field of OLEDs are small molecules.

As used herein, “top” means furthest away from the substrate, while “bottom” means closest to the substrate. Where a first layer is described as “disposed over” a second layer, the first layer is disposed further away from substrate. There may be other layers between the first and second layer, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

As used herein, and as would be generally understood by one skilled in the art, a first “Highest Occupied Molecular Orbital” (HOMO) or “Lowest Unoccupied Molecular Orbital” (LUMO) energy level is “greater than” or “higher than” a second HOMO or LUMO energy level if the first energy level is closer to the vacuum energy level. Since ionization potentials (IP) are measured as a negative energy relative to a vacuum level, a higher HOMO energy level corresponds to an IP having a smaller absolute value (an IP that is less negative). Similarly, a higher LUMO energy level corresponds to an electron affinity (EA) having a smaller absolute value (an EA that is less negative). On a conventional energy level diagram, with the vacuum level at the top, the LUMO energy level of a material is higher than the HOMO energy level of the same material. A “higher” HOMO or LUMO energy level appears closer to the top of such a diagram than a “lower” HOMO or LUMO energy level.

As used herein, and as would be generally understood by one skilled in the art, a first work function is “greater than” or “higher than” a second work function if the first work function has a higher absolute value. Because work functions are generally measured as negative numbers relative to vacuum level, this means that a “higher” work function is more negative. On a conventional energy level diagram, with the vacuum level at the top, a “higher” work function is illustrated as further away from the vacuum level in the downward direction. Thus, the definitions of HOMO and LUMO energy levels follow a different convention than work functions.

More details on OLEDs, and the definitions described above, can be found in U.S. Pat. No. 7,279,704, which is incorporated herein by reference herein in its entirety.

OLED displays are commonly used in mobile devices, smartwatches, computer monitors, and televisions. The OLED displays may be Active-Matrix organic light emitting diode (AMOLED) or Passive-Matrix organic light emitting diode (PMOLED). A reliable and flexible OLED display module is needed to manufacture devices with innovative design. Currently, it is difficult to manufacture flexible OLED display modules to reliably and repetitively flex (radius of curvature) to less than 1 mm. Most flexible OLED module designs are too thick for repetitive flexing. For reliable and repetitive flexing, a flexible OLED display module should have a thickness approximately 10% of the desired radius of curvature for flexing, or approximately 100 μm. Current manufacturing of OLED display modules results in module of several hundred microns, which is too thick and results in poor display flexibility.

### SUMMARY

A flexible OLED display module that is capable of repetitive flexing and having a low radius of curvature is provided.

According to an embodiment, a flexible OLED display module may include a first stack having a substrate, a backplane disposed on the substrate, and an organic electroluminescent layer formed on the backplane. The flexible OLED display module may further include a second stack having a lid layer, and a polarizer deposited on the lid layer. The first stacked laminated with the second stack.

In an embodiment of the invention disclosed herein, the flexible OLED display module may include a touch panel disposed in a neutral plane of the flexible OLED display module.

In an embodiment of the invention disclosed herein, the deposited polarizer may be a circular polarizer including a linear polarizer and a quarter wave retarder.

According to another embodiment, a method of manufacturing a flexible OLED display module is provided. The method may include providing a substrate. Forming a backplane on the substrate. An organic electroluminescent layer may be formed on the backplane. The substrate, backplane, and organic electroluminescent layer forming a first stack. The method may also include providing a lid. A polarizing film may be deposited on the lid to form a second stack. The second stack may be dried, and then the second stack and first stack may be laminated.

### BRIEF DESCRIPTION OF THE DRAWINGS

FIG. 1 shows an organic light emitting device.

FIG. 2 shows an inverted organic light emitting device that does not have a separate electron transport layer.

FIG. 3A shows a flexible OLED display module according to an embodiment of the present invention.

FIG. 3B shows a flexible OLED display module according to another embodiment of the present invention.

### DETAILED DESCRIPTION

Generally, an OLED comprises at least one organic layer disposed between and electrically connected to an anode and a cathode. When a current is applied, the anode injects holes and the cathode injects electrons into the organic layer(s). The injected holes and electrons each migrate toward the oppositely charged electrode. When an electron and hole localize on the same molecule, an “exciton,” which is a localized electron-hole pair having an excited energy state, is formed. Light is emitted when the exciton relaxes via a photo-emissive mechanism. In some cases, the exciton may be localized on an excimer or an exciplex. Non-radiative mechanisms, such as thermal relaxation, may also occur, but are generally considered undesirable.

The initial OLEDs used emissive molecules that emitted light from their singlet states (“fluorescence”) as disclosed, for example, in U.S. Pat. No. 4,769,292, which is incorporated by reference herein in its entirety. Fluorescent emission generally occurs in a time frame of less than 10 nanoseconds.

More recently, OLEDs having emissive materials that emit light from triplet states (“phosphorescence”) have been demonstrated. Baldo et al., “Highly Efficient Phosphorescent Emission from Organic Electroluminescent Devices,” Nature, vol. 395, 151-154, 1998; (“Baldo-I”) and Baldo et al., “Very high-efficiency green organic light-emitting devices based on electro-phosphorescence,” Appl. Phys. Lett., vol. 75, No. 3, 4-6 (1999) (“Baldo-II”), are incorporated by reference herein in their entireties. Phosphorescence is described in more detail in U.S. Pat. No. 7,279,704 at cols. 5-6, which are incorporated by reference.

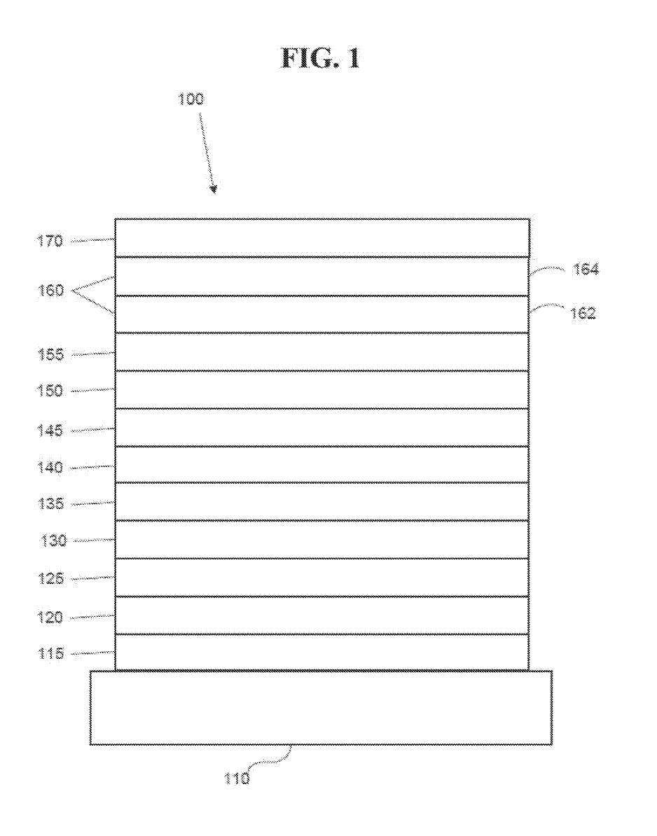

FIG. 1 shows an organic light emitting device 100. The figures are not necessarily drawn to scale. Device 100 may include a substrate 110, an anode 115, a hole injection layer 120, a hole transport layer 125, an electron blocking layer 130, an emissive layer 135, a hole blocking layer 140, an electron transport layer 145, an electron injection layer 150, a protective layer 155, a cathode 160, and a barrier layer 170. Cathode 160 may be a compound cathode having a first conductive layer 162 and a second conductive layer 164. Device 100 may be fabricated by depositing the layers described, in order. The properties and functions of these various layers, as well as example materials, are described in more detail in U.S. Pat. No. 7,279,704 at cols. 6-10, which are incorporated by reference.

More examples for each of these layers are available. For example, a flexible and transparent substrate-anode combination is disclosed in U.S. Pat. No. 5,844,363, which is incorporated by reference herein in its entirety. An example of a p-doped hole transport layer is m-MTDATA doped with F₄-TCNQ at a molar ratio of 50:1, as disclosed in U.S. Patent Application Publication No. 2003/0230980, which is incorporated by reference herein in its entirety. Examples of emissive and host materials are disclosed in U.S. Pat. No. 6,303,238 to Thompson et al., which is incorporated by reference herein in its entirety. An example of an n-doped electron transport layer is BPhen doped with Li at a molar ratio of 1:1, as disclosed in U.S. Patent Application Publication No. 2003/0230980, which is incorporated by reference herein in its entirety. U.S. Pat. Nos. 5,703,436 and 5,707,745, which are incorporated by reference herein in their entireties, disclose examples of cathodes including compound cathodes having a thin layer of metal such as Mg:Ag with an overlying transparent, electrically-conductive, sputter-deposited ITO layer. The theory and use of blocking layers is described in more detail in U.S. Pat. No. 6,097,147 and U.S. Patent Application Publication No. 2003/0230980, which are incorporated by reference herein in their entireties. Examples of injection layers are provided in U.S. Patent Application Publication No. 2004/0174116, which is incorporated by reference herein in its entirety. A description of protective layers may be found in U.S. Patent Application Publication No. 2004/0174116, which is incorporated by reference herein in its entirety.

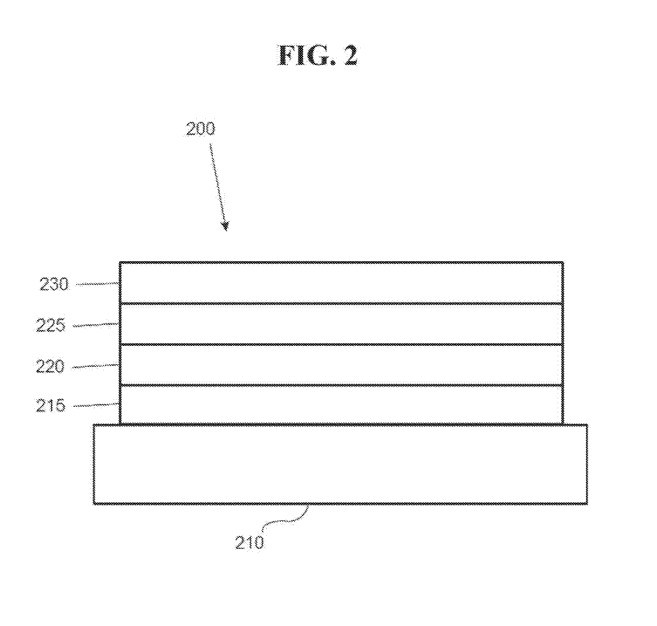

FIG. 2 shows an inverted OLED 200. The device includes a substrate 210, a cathode 215, an emissive layer 220, a hole transport layer 225, and an anode 230. Device 200 may be fabricated by depositing the layers described, in order. Because the most common OLED configuration has a cathode disposed over the anode, and device 200 has cathode 215 disposed under anode 230, device 200 may be referred to as an “inverted” OLED. Materials similar to those described with respect to device 100 may be used in the corresponding layers of device 200. FIG. 2 provides one example of how some layers may be omitted from the structure of device 100.

The simple layered structure illustrated in FIGS. 1 and 2 is provided by way of non-limiting example, and it is understood that embodiments of the invention may be used in connection with a wide variety of other structures. The specific materials and structures described are exemplary in nature, and other materials and structures may be used. Functional OLEDs may be achieved by combining the various layers described in different ways, or layers may be omitted entirely, based on design, performance, and cost factors. Other layers not specifically described may also be included. Materials other than those specifically described may be used. Although many of the examples provided herein describe various layers as comprising a single material, it is understood that combinations of materials, such as a mixture of host and dopant, or more generally a mixture, may be used. Also, the layers may have various sublayers. The names given to the various layers herein are not intended to be strictly limiting. For example, in device 200, hole transport layer 225 transports holes and injects holes into emissive layer 220, and may be described as a hole transport layer or a hole injection layer. In one embodiment, an OLED may be described as having an “organic layer” disposed between a cathode and an anode. This organic layer may comprise a single layer, or may further comprise multiple layers of different organic materials as described, for example, with respect to FIGS. 1 and 2.

Structures and materials not specifically described may also be used, such as OLEDs comprised of polymeric materials (PLEDs) such as disclosed in U.S. Pat. No. 5,247,190 to Friend et al., which is incorporated by reference herein in its entirety. By way of further example, OLEDs having a single organic layer may be used. OLEDs may be stacked, for example as described in U.S. Pat. No. 5,707,745 to Forrest et al, which is incorporated by reference herein in its entirety. The OLED structure may deviate from the simple layered structure illustrated in FIGS. 1 and 2. For example, the substrate may include an angled reflective surface to improve out-coupling, such as a mesa structure as described in U.S. Pat. No. 6,091,195 to Forrest et al., and/or a pit structure as described in U.S. Pat. No. 5,834,893 to Bulovic et al., which are incorporated by reference herein in their entireties.

Unless otherwise specified, any of the layers of the various embodiments may be deposited by any suitable method. For the organic layers, preferred methods include thermal evaporation, ink-jet, such as described in U.S. Pat. Nos. 6,013,982 and 6,087,196, which are incorporated by reference herein in their entireties, organic vapor phase deposition (OVPD), such as described in U.S. Pat. No. 6,337,102 to Forrest et al., which is incorporated by reference herein in its entirety, and deposition by organic vapor jet printing (OVJP), such as described in U.S. Pat. No. 7,431,968, which is incorporated by reference herein in its entirety. Other suitable deposition methods include spin coating and other solution based processes. Solution based processes are preferably carried out in nitrogen or an inert atmosphere. For the other layers, preferred methods include thermal evaporation. Preferred patterning methods include deposition through a mask, cold welding such as described in U.S. Pat. Nos. 6,294,398 and 6,468,819, which are incorporated by reference herein in their entireties, and patterning associated with some of the deposition methods such as ink-jet and OVJD. Other methods may also be used. The materials to be deposited may be modified to make them compatible with a particular deposition method. For example, substituents such as alkyl and aryl groups, branched or unbranched, and preferably containing at least 3 carbons, may be used in small molecules to enhance their ability to undergo solution processing. Substituents having 20 carbons or more may be used, and 3-20 carbons is a preferred range. Materials with asymmetric structures may have better solution processibility than those having symmetric structures, because asymmetric materials may have a lower tendency to recrystallize. Dendrimer substituents may be used to enhance the ability of small molecules to undergo solution processing.

Devices fabricated in accordance with embodiments of the present invention may further optionally comprise a barrier layer. One purpose of the barrier layer is to protect the electrodes and organic layers from damaging exposure to harmful species in the environment including moisture, vapor and/or gases, etc. The barrier layer may be deposited over, under or next to a substrate, an electrode, or over any other parts of a device including an edge. The barrier layer may comprise a single layer, or multiple layers. The barrier layer may be formed by various known chemical vapor deposition techniques and may include compositions having a single phase as well as compositions having multiple phases. Any suitable material or combination of materials may be used for the barrier layer. The barrier layer may incorporate an inorganic or an organic compound or both. The preferred barrier layer comprises a mixture of a polymeric material and a non-polymeric material as described in U.S. Pat. No. 7,968,146, PCT Pat. Application Nos. PCT/US2007/023098 and PCT/US2009/042829, which are incorporated by reference herein in their entireties. To be considered a “mixture”, the aforesaid polymeric and non-polymeric materials comprising the barrier layer should be deposited under the same reaction conditions and/or at the same time. The weight ratio of polymeric to non-polymeric material may be in the range of 95:5 to 5:95. The polymeric material and the non-polymeric material may be created from the same precursor material. In one example, the mixture of a polymeric material and a non-polymeric material consists essentially of polymeric silicon and inorganic silicon.

Devices fabricated in accordance with embodiments of the invention can be incorporated into a wide variety of electronic component modules (or units) that can be incorporated into a variety of electronic products or intermediate components. Examples of such electronic products or intermediate components include display screens, lighting devices such as discrete light source devices or lighting panels, etc. that can be utilized by the end-user product manufacturers. Such electronic component modules can optionally include the driving electronics and/or power source(s). Devices fabricated in accordance with embodiments of the invention can be incorporated into a wide variety of consumer products that have one or more of the electronic component modules (or units) incorporated therein. Such consumer products would include any kind of products that include one or more light source(s) and/or one or more of some type of visual displays. Some examples of such consumer products include flat panel displays, computer monitors, medical monitors, televisions, billboards, lights for interior or exterior illumination and/or signaling, heads-up displays, fully or partially transparent displays, flexible displays, laser printers, telephones, cell phones, tablets, phablets, personal digital assistants (PDAs), wearable device, laptop computers, digital cameras, camcorders, viewfinders, micro-displays, 3-D displays, vehicles, a large area wall, theater or stadium screen, or a sign. Various control mechanisms may be used to control devices fabricated in accordance with the present invention, including passive matrix and active matrix. Many of the devices are intended for use in a temperature range comfortable to humans, such as 18 degrees C. to 30 degrees C., and more preferably at room temperature (20-25 degrees C.), but could be used outside this temperature range, for example, from −40 degree C. to +80 degree C.

The materials and structures described herein may have applications in devices other than OLEDs. For example, other optoelectronic devices such as organic solar cells and organic photodetectors may employ the materials and structures. More generally, organic devices, such as organic transistors, may employ the materials and structures.

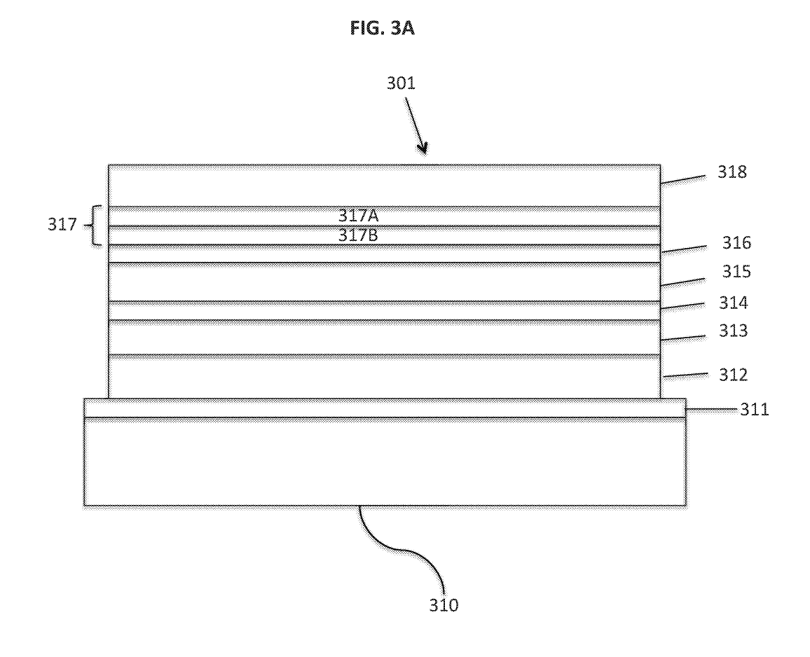

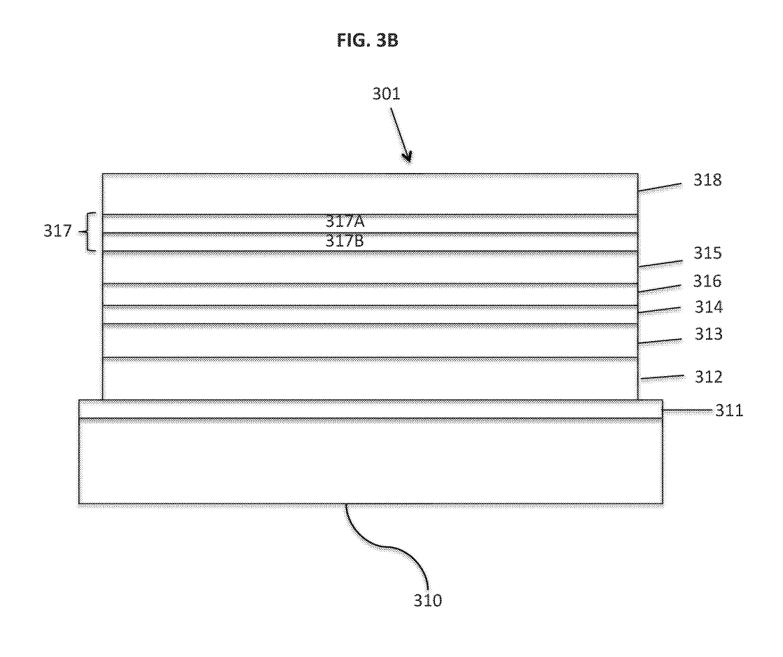

FIGS. 3A and 3B show a flexible OLED display module 301 in accordance with embodiments of the present invention. Again, the figures are not necessarily drawn to scale but are used for illustration purposes. The flexible OLED display module 301 contains a substrate, for example, an active substrate 310. An active or passive backplane 312 and organic electroluminescent layer 313 may be formed on the active substrate 310. The OLED displays may be Active-Matrix organic light emitting diode (AMOLED) or Passive-Matrix organic light emitting diode (PMOLED). The flexible OLED display module 301 may also contain a second substrate opposite the active substrate 310, for example, a lid 318. The substrates may be plastic substrates having a glass transition temperature of less than 200° C. The substrates may also be a thin metal foil or other suitable materials. The flexible OLED display module 301 may also include encapsulations 311, 314, polarizer 317, color filters (not shown), a touch panel 315, and sufficient ruggedization (top protective cover) to ensure a display is not damaged during normal use. For description purposes, the substrate and its films or components is known as a stack. For example, a first substrate may include the active substrate 310, the encapsulations 311, 314, the backplane 312, and the organic electroluminescent layer 313. A second stack may include the lid 318, the polarizer 317, and the color filters. Although the first and second stacks have been described above, it is understood the layers and components may be arranged in various orders within the stacks, and both the first and second stacks may contain additional layers and components other than those described. The touch panel 315 may be disposed in either one of the first and second stacks. A neutral plane for bending should lie within the region bounded by the two stacks. The touch panel 315 should be disposed within 10 μm of the neutral plane. The first stack and the second stack may be laminated together using an Optically Clear Adhesive (OCA). For visual description, FIGS. 3A and 3B show a lamination layer 316. Other methods of lamination may be used, such as a pressure sensitive adhesive, epoxy or other known and suitable lamination techniques. The lamination layer 316 may laminate the touch panel 315 with the first stack or the second stack. It is understood that a flexible OLED display module 301 may not contain a touch panel 315. A thickness of each of the first and second stacks is less than 60 μm, preferably less than 50 μm. A thickness of the OLED display module 301 is less than 150 μm, preferably less than 100 μm.

As disclosed above and shown in FIGS. 3A and 3B, the touch panel 315 may be disposed in either one of the first and second stacks using standard technologies. Typically, the touch panel 315 is the least flexible component within the flexible OLED display module 301. To minimize issues with repetitive flexing of the touch panel 315, the touch panel 315 should be disposed close to the neutral plane. The touch panel should be disposed within 10 μm of the neutral plane. As shown in FIGS. 3A and 3B, the touch panel 315 is placed on either the active substrate 310 (first stack) or the lid 318 (second stack), but in each case as the top layer closest to a plane of lamination.

The polarizer 317 may be a circular polarizer, which may consist of two optical agents, a linear polarizer 317A and a quarter wave retarder 3173 or birefringent material. Lyotropic liquids crystals may be used as the source of the birefringent and the linear polarizer 317A. However, these materials contain water and other moisture. Therefore, the polarizer 317 should be cured and dried prior to use. In other words, the polarizer 317 is deposited onto the lid 318, the stacks are dried, and then the two stacks are laminated together. The drying ensures that all moistures are removed from the final flexible OLED display module 301, which increases the lifetime of the flexible OLED display module 301.

The flexible OLED display module 301 may be capable of operation at a sunlight readable luminance value (e.g., 700 cd/m2). Furthermore, according to embodiments of the present invention, the flexible OLED display module 301 may not experience an operating temperature increase of more than 26° C. An operating temperature increase may be an increase in temperature due to the heat generated by the display. The display may generate heat due to factors such as, but not limited to, frictional force, vibrations, current flow, energy conversion, or the like. For example, a flexible OLED display module 301 may experience a rise in operating temperature due to the inefficient device operation where part of the energy is converted into heat instead of generating light. An increase in temperature due to ambient conditions may not be considered in calculating an operating temperature increase. Such ambient conditions may include, but are not limited to, body heat, sunlight, weather conditions, external air flow, external flames, or the like. For example, if a display is operated with an initial ambient temperature of 25° C. and the ambient temperature increases to 30° C. within an hour of operation, then the 5° C. increase in ambient temperature should not be a factor in calculating the operating temperature rise. In the same example, if the overall temperature of the display increases to 50° C. after an hour of operation, the rise in operating temperature is 20° C. (50° C. minus 30° C.). Additional information on luminance value is disclosed, for example, in U.S. Pat. No. 8,766,531, which is incorporated by reference herein in its entirety.

As previously described, various techniques may be used to fabricate one or more layers for the various embodiments of the flexible OLED display module 301 of the present invention. After fabricating the first stack, which may include an active substrate 310, encapsulations 311, 314, a backplane 312, and OLED pixels 313, the second stack is fabricated by depositing a polarizer 317 onto a lid 318. The polarizer 317 may be a circular polarizer, which is formed of a linear polarizer 317A and a quarter wave retarder 3173. The second stack may also include color filters. A touch panel 315 is formed in either one of the first stack and the second stack. The touch panel 315 is disposed close to the middle of the two stacks, i.e., close to the neutral plane. In general, the touch panel 315 is disposed within 10 μm of the neutral plane of the flexible OLED display module 301. Prior to laminating the first and second stacks together, and to remove all traces of moisture from the polarizer 317, the stacks are thoroughly dried. After the drying process, the first stack is laminated with the second stack.

It is understood that the various embodiments described herein are by way of example only, and are not intended to limit the scope of the invention. For example, many of the materials and structures described herein may be substituted with other materials and structures without deviating from the spirit of the invention. The present invention as claimed may therefore include variations from the particular examples and preferred embodiments described herein, as will be apparent to one of skill in the art. It is understood that various theories as to why the invention works are not intended to be limiting.

1. A flexible OLED display module, comprising:
a first stack comprising:
a substrate,
a backplane disposed on the substrate, and
an organic electroluminescent layer formed on the backplane; and
a second stack laminated with the first stack comprising:
a lid layer, and
a deposited polarizer formed on the lid layer.

2. (canceled)

3. The flexible OLED display module of claim 1, wherein a thickness of the first stack is less than 60 μm, and a thickness of the second stack is less than 60 μm.

4-10. (canceled)

11. The flexible OLED display module of claim 1, wherein the flexible OLED display module is capable of having a radius of curvature of less than 1 mm.

12. (canceled)

13. The flexible OLED display module of claim 1, wherein the flexible OLED display module operates at a luminance value of at least 700 cd/m² without exceeding an operation temperature increase of 26° C.

14. The flexible OLED display module of claim 1, wherein the flexible OLED display module is integrated in one of a flat panel display, computer monitor, medical monitor, television, billboard, lights for interior or exterior illumination and signaling, heads-up display, laser printer, telephone, cell phone, tablet, phablet, personal digital assistant (PDA), wearable device, laptop computer, digital camera, camcorder, viewfinder, micro-display, 3-D display, vehicle, a large area wall, theater or stadium screen, and a sign.

15. A flexible OLED display module, comprising:
a first stack comprising:
a substrate,
a backplane disposed on the substrate, and
an organic electroluminescent layer formed on the backplane;
a second stack laminated with the first stack comprising:
a lid,
a deposited polarizer formed on the lid, and
a touch panel disposed in one of the first stack and the second stack.

16. The flexible OLED display module of claim 15, wherein a thickness of the flexible OLED display module is less than 150 μm.

17. (canceled)

18. The flexible OLED display module of claim 15, wherein the laminate between the first stack and the second stack is selected from one of a pressure sensitive adhesive, epoxy, and an optically clear adhesive.

19. The flexible OLED display module of claim 15, wherein the touch panel is laminated to one of the first stack and the second stack.

20. The flexible OLED display module of claim 15, wherein the touch panel is disposed within 10 μm a neutral plane of the flexible OLED display module.

21. The flexible OLED display module of claim 15, wherein the deposited polarizer is a deposited circular polarizer comprising a deposited linear polarizer and a deposited quarter wave retarder.

22. (canceled)

23. The flexible OLED display module of claim 15, wherein a color filter is disposed in at least one of the first stack and the second stack.

24. The flexible OLED display module of claim 15, wherein the flexible OLED display device is capable of having a radius of curvature of less than 2 mm.

25-26. (canceled)

27. The flexible OLED display module of claim 15, wherein the wherein the substrate is a plastic having a glass transition temperature of less than 200° C.

28. (canceled)

29. A method of manufacturing a flexible OLED display module, comprising:
providing a substrate;
forming a backplane on the substrate;
providing an organic electroluminescent layer on the backplane, wherein the substrate, backplane, and organic electroluminescent layer form a first stack;
providing a lid;
depositing a polarizing film on the lid to form a second stack;
drying the second stack; and
laminating the second stack with the first stack.

30. The method of claim 29, wherein a thickness of the flexible OLED display device is formed to be less than 150 μm.

31. (canceled)

32. The method of claim 29, wherein the laminating step laminates the first stack and the second stack with a laminate selected from one of a pressure sensitive adhesive, epoxy, and an optically clear adhesive.

33. The method of claim 29, further comprising disposing a touch panel in one of the first stack and the second stack.

34. (canceled)

35. The method of claim 29, wherein the deposited polarizer film is a deposited circular polarizer comprising a deposited linear polarizer and a deposited quarter wave retarder.

36. The method of claim 29, further comprising:
providing an encapsulation layer on at least one of the first stack and the second stack; and
providing a color filter in at least one of the first stack and the second stack.

37. (canceled)
